(19) United States
(12) Patent Application Publication
(10) Pub. No.: US 2026/0324093 A1
(43) Pub. Date: Oct. 15, 2026

(54) ESD/EOS PROTECTION DEVICE

(71) Applicant: United Microelectronics Corp., Hsinchu (TW)

(72) Inventors: Ya-Ting LIN, Hsinchu City (TW); Ta-Yi Huang, New Taipei City (TW); Jih-San Lee, Hsinchu City (TW); Tien-Hao Tang, Hsinchu City (TW)

(21) Appl. No.: 19/206,085

(22) Filed: May 13, 2025

(30) Foreign Application Priority Data
Apr. 10, 2025 (TW) 114113554

(51) Int. Cl. H10D 89/60

(52) U.S. Cl. CPC H10D 89/813

(57) ABSTRACT

ESD/EOS protection devices are provided. The ESD/EOS protection device includes a fin structure formed of a semiconductor material and over a semiconductor substrate, a first source/drain region in the fin structure, a second source/drain region in the fin structure, a gate structure over the fin structure and between the first source/drain region and the second source/drain region, a first dummy gate structure over the fin structure, a first doped region in the fin structure and between the first source/drain region and the second source/drain region, and a first doped layer under the first dummy gate structure and extending from the second source/drain region to the first doped region. A lower surface of the first doped layer is higher than a lower surface of the first doped region.

This application claims the benefit of Taiwan application Serial No. 114113554, filed Apr. 10, 2025, the subject matters of which are incorporated herein by reference.

### BACKGROUND

### Technical Field

The disclosure relates to semiconductor structures, and more particularly to ESD/EOS protection devices.

### Description of the Related Art

Electrostatic discharge (ESD) events and electrical over stress (EOS) events are common causes of damage or failure of electronic equipment. An ESD event is the momentary discharge of electricity between objects that are at different potentials. An ESD event can involve voltages of hundreds or even thousands of volts. An EOS event can be a momentary event lasting only milliseconds or can occur continuously as long as the conditions persist. An EOS event can occur at low voltage levels, typically less than 100 volts. The industry usually uses ESD/EOS protection devices to prevent ESD events and EOS events from damaging electronic equipment. Fin field effect transistor (FinFET) structures can be used to form ESD/EOS protection devices. However, the protection capabilities of existing FinFET-based ESD/EOS protection devices are still insufficient.

### SUMMARY

The present disclosure provides ESD/EOS protection devices with good protection capabilities against both ESD events and EOS events.

According to an embodiment of the present disclosure, an ESD/EOS protection device is provided. The ESD/EOS protection device includes a fin structure formed of a semiconductor material and over a semiconductor substrate, a first source/drain region in the fin structure, a second source/drain region in the fin structure, a gate structure over the fin structure and between the first source/drain region and the second source/drain region, a first dummy gate structure over the fin structure, a first doped region in the fin structure and between the first source/drain region and the second source/drain region, and a first doped layer under the first dummy gate structure and extending from the second source/drain region to the first doped region. A lower surface of the first doped layer is higher than a lower surface of the first doped region.

According to an embodiment of the present disclosure, an ESD/EOS protection device is provided. The ESD/EOS protection device includes a fin structure formed of a semiconductor material and over a semiconductor substrate, a first source/drain region in the fin structure, a second source/drain region in the fin structure, a gate structure over the fin structure and between the first source/drain region and the second source/drain region, a first dummy gate structure over the fin structure, a first doped region in the fin structure and between the first source/drain region and the second source/drain region, a first doped layer under the first dummy gate structure and extending from the second source/drain region to the first doped region, a second dummy gate structure over the fin structure, a second doped region in the fin structure, and a second doped layer under the second dummy gate structure and extending from the first doped region to the second doped region. The first doped layer and the second doped layer are separated from each other.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a circuit diagram of an ESD/EOS protection device and an internal circuit according to some embodiments of the present disclosure.

FIG. 2 illustrates a schematic sectional view of a transistor of the ESD/EOS protection device according to some embodiments of the present disclosure.

FIG. 3 illustrates a schematic view of a transistor of the ESD/EOS protection device according to some embodiments of the present disclosure.

FIGS. 4A, 4B, 5A, 5B, 6A, 6B and 6C show graphs of current-voltage (I-V) characteristics obtained from TLP tests.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “adjoin” refers to “adjacent to and contact”. As used in the specification and the appended claims, term “dummy gate structure” means that the current between the source and drain of the transistor is not controlled by this gate structure.

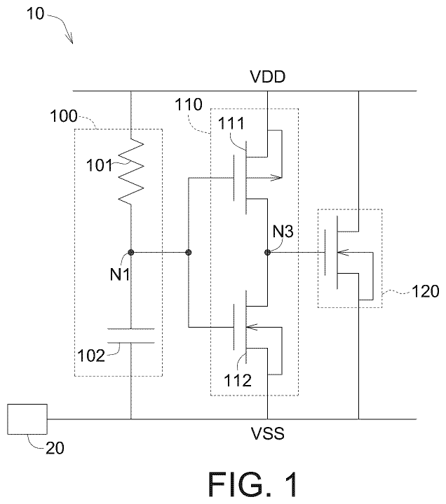

Referring to FIG. 1, FIG. 1 illustrates a circuit diagram of an ESD/EOS protection device 10 and an internal circuit 20 according to some embodiments of the present disclosure. The ESD/EOS protection device 10 can be electrically connected to the internal circuit 20 to discharge the charge accumulated by the ESD event during the ESD event to protect the internal circuit 20. The internal circuit 20 may include one or more active elements and/or one or more passive elements. The active elements include, but are not limited to, transistors and diodes. The transistors include, but are not limited to, planar field-effect transistors, fin field-effect transistors (FinFET), nanowire field-effect transistors, nanosheet field-effect transistors, complementary metal-oxide-semiconductor (CMOS) transistor, bipolar junction transistors (BJT), high-voltage transistors and high frequency transistors. The passive elements include, but are not limited to, capacitors, inductors, fuses and resistors.

The ESD/EOS protection device 10 includes a detection circuit 100, a control circuit 110 and a transistor 120. The detection circuit 100 is electrically connected between a voltage VDD and a voltage VSS. In an embodiment, the voltage VDD can be any voltage suitable for operating the internal circuit 20. In an embodiment, the voltage VSS can be a ground voltage. The detection circuit 100 may include a resistor 101 and a capacitor 102. A first terminal of the resistor 101 is electrically connected to the voltage VDD. A second terminal of the resistor 101 is electrically connected to a node N1. A first terminal of the capacitor 102 is electrically connected to the node N1. A second terminal of the capacitor 102 is electrically connected to the voltage VSS. The resistor 101 and the capacitor 102 can form a resistor-capacitor (RC) circuit. In an embodiment, the detection circuit 100 can include any number of resistors 101 and any number of capacitors 102. The control circuit 110 is electrically connected between the voltage VDD and the voltage VSS. The control circuit 110 may include a P-type metal-oxide-semiconductor (PMOS) transistor 111 and a N-type metal-oxide-semiconductor (NMOS) transistor 112. The source of the PMOS transistor 111 is electrically connected to the voltage VDD. The gate of the PMOS transistor 111 is electrically connected to the node N1. The drain of the PMOS transistor 111 is electrically connected to a node N3. The source of the NMOS transistor 112 is electrically connected to the voltage VSS. The gate of the NMOS transistor 112 is electrically connected to the node N1. The drain of the NMOS transistor 112 is electrically connected to the node N3. The control circuit 110 can be an inverter. In an embodiment, the control circuit 110 can invert the voltage at the node N1 that rises slowly, and the voltage at the node N3 rises quickly. In an embodiment, the control circuit 110 can invert the voltage at the node N1 that rises quickly, and the voltage at the node N3 rises slowly. In an embodiment, the PMOS transistor 111 and the NMOS transistor 112 can be configured to generate an inverted output signal in response to an input signal. The transistor 120 is electrically connected between the voltage VDD and the voltage VSS. The transistor 120 may be or may include a NMOS transistor. The source of the transistor 120 is electrically connected to the voltage VSS. The gate of the transistor 120 is electrically connected to the node N3. The drain of the transistor 120 is electrically connected to the voltage VDD.

In an embodiment, during the ESD event or EOS event, the node N1 between the resistor 101 and the capacitor 102 is pulled down to the voltage VSS; the voltage at the node N3 is pulled up to a high voltage level after inverting by the control circuit 110; the transistor 120 is turned on to discharge the charge accumulated by the ESD event or EOS event. In an embodiment, during normal operation without an ESD event or EOS event, the voltage VDD is electrically connected to the detection circuit 100, the voltage at the node N1 is high; the voltage at the node N3 is low after inverting by the control circuit 110, so that the transistor 120 is turned off and the voltage VDD can be supplied to the internal circuit 20 for operations.

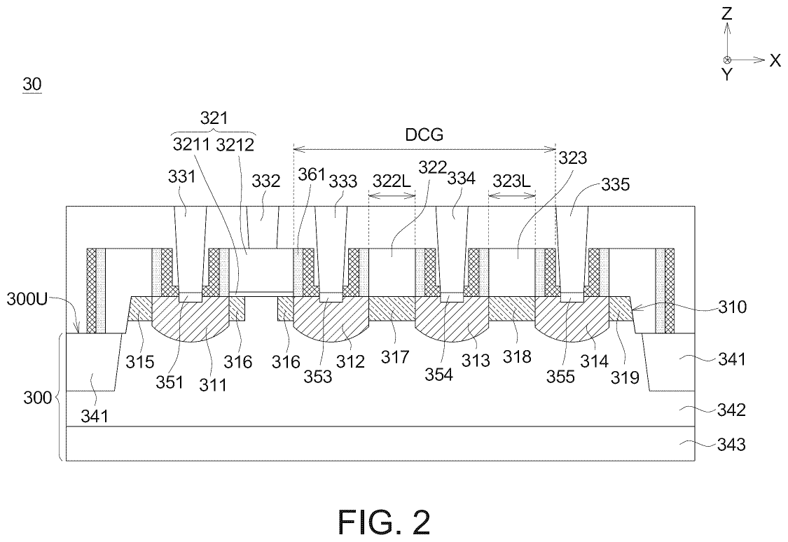

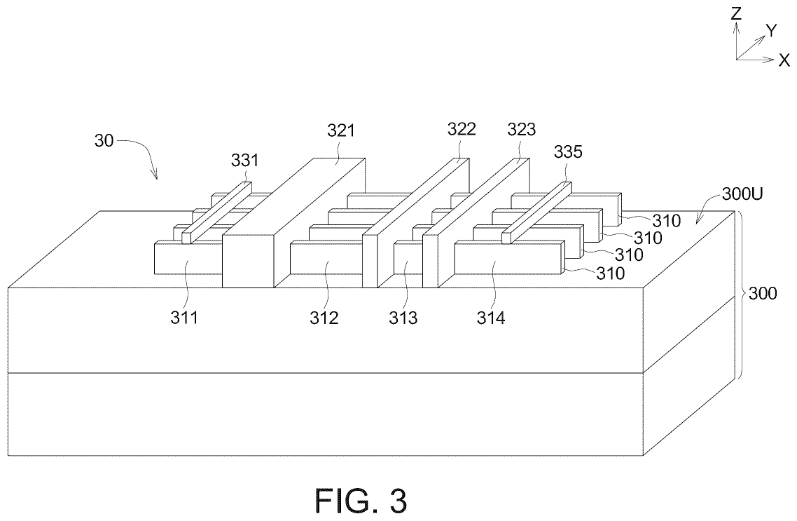

Referring to FIGS. 2 and 3, FIG. 2 illustrates a schematic sectional view of a transistor 30 according to some embodiments of the present disclosure, and FIG. 3 illustrates a schematic view of the transistor 30 according to some embodiments of the present disclosure. The transistor 30 shown in FIGS. 2 and 3 can be the transistor 120 shown in FIG. 1. The X direction, the Y direction and the Z direction shown in FIGS. 2 and 3 are perpendicular to each other.

The transistor 30 includes a semiconductor substrate 300, a fin structure 310, a first source/drain region 311, a second source/drain region 314, a gate structure 321, a dummy gate structure 323, a doped region 313 and a doped layer 318. The semiconductor substrate 300 may include or may be a silicon substrate, an epitaxial silicon substrate, a silicon germanium substrate, a silicon carbide substrate, a silicon-on-insulator (SOI) substrate, or a substrate formed of other suitable semiconductor materials. The fin structure 310 may be disposed over the semiconductor substrate 300 in the Z direction. The fin structure 310 may protrude upward from an upper surface 300U of the semiconductor substrate 300. The fin structure 300 may extend in the X direction. The fin structure 300 can be formed of a semiconductor material, such as silicon, epitaxial silicon, silicon germanium or silicon carbide. In an embodiment, the fin structure 310 can include a first type dopant or a second type dopant. The conductivity type of the first type dopant is different from that of the second type dopant. The gate structure 321 may be disposed over the semiconductor substrate 300 in the Z direction. The gate structure 321 may be disposed over the fin structure 310. The gate structure 321 may extend in the Y direction. The gate structure 321 may cover an upper surface and two opposite sidewalls of the fin structure 310. The gate structure 321 is between the first source/drain region 311 and the second source/drain region 314. The gate structure 321 can include a gate dielectric layer 3211 and a gate material layer 3212 on the gate dielectric layer 3211. In an embodiment, the gate material layer 3212 can include a high dielectric constant dielectric layer, a work function metal layer and a conductive layer. In an embodiment, the gate material layer 3212 can include polycrystalline silicon. The first source/drain region 311 and second source/drain region 314 are disposed in the fin structure 310. The first source/drain region 311 and second source/drain region 314 can be disposed in the fin structure 310 and in the substrate 300 under the fin structure 310. The first source/drain region 311 and second source/drain region 314 may be disposed on opposite sides of the gate structure 321 in the X direction. In the present embodiment, the first source/drain region 311 can be functioned as the source of the transistor 30, the second source/drain region 314 can be functioned as the drain of the transistor 30, but the present disclosure is not limited thereto. The first source/drain region 311 and second source/drain region 314 may include a first type dopant or a second type dopant.

The dummy gate structure 323 may be disposed over the semiconductor substrate 300 in the Z direction. The dummy gate structure 323 may be disposed over the fin structure 310. The dummy gate structure 323 may extend in the Y direction. The dummy gate structure 323 may cover an upper surface and two opposite sidewalls of the fin structure 310. The dummy gate structure 323 may be disposed between the gate structure 321 and the second source/drain region 314 in the X direction. In an embodiment, the dummy gate structure 323 can include a dummy gate dielectric layer and a dummy gate material layer on the dummy gate dielectric layer, and the dummy gate material layer can include a high dielectric constant dielectric layer, a work function metal layer and a conductive layer. In an embodiment, the dummy gate material layer can include polycrystalline silicon. In an embodiment, the dummy gate structure 323 and the gate structure 321 can have the same structure and material. The doped region 313 is disposed in the fin structure 310. The doped region 313 may be disposed in the fin structure 310 and in the semiconductor substrate 300 under the fin structure 310. The doped region 313 may be disposed between the first source/drain region 311 and the second source/drain region 314. The doped region 313 may be disposed on a side of the dummy gate structure 323 and between the dummy gate structure 323 and the gate structure 321. The doped region 313 and the second source/drain region 314 may be disposed on opposite sides of the dummy gate structure 323 in the X direction. The doped region 313 may include a first type dopant or a second type dopant. The doped layer 318 is disposed in the fin structure 310. The doped layer 318 may be disposed over the semiconductor substrate 300 in the Z direction. The doped layer 318 can be completely disposed in the fin structure 310 without extending into the semiconductor substrate 300. The doped layer 318 may be disposed under the dummy gate structure 323 in the Z direction. The doped layer 318 may adjoin the second source/drain region 314 and the doped region 313. The doped layer 318 extends from the second source/drain region 314 to the doped region 313. The doped layer 318 may include a first type dopant or a second type dopant. A lower surface of the doped layer 318 can be higher than a lower surface of the doped region 313 in the Z direction.

The transistor 30 may include one or more dummy gate structures, one or more doped layers and one or more doped regions. The number of the doped layers and the number of the doped regions may depend on the number of the dummy gate structures. In an embodiment, when the transistor includes only one dummy gate structure (e.g., the dummy gate structure 323) between the gate structure 321 and the second source/drain region 314, the transistor 30 includes a doped layer (e.g., the doped layer 318) under the dummy gate structure and a doped region (e.g., the doped region 313) between the dummy gate structure and the gate structure 321; in this case, the doped region 313 can extend from a side of the gate structure 321 to the doped layer 318. In an embodiment, when the transistor 30 includes two dummy gate structures (e.g., the dummy gate structure 323 and the dummy gate structure 322) between the gate structure 321 and the second source/drain region 314, the transistor 30 includes two doped layers (e.g., the doped layer 318 and the doped layer 317) under the dummy gate structures and two doped regions (e.g., the doped region 313 and the doped region 312) between the dummy gate structures and the gate structure 321, as shown in FIG. 2. The dummy gate structure 322 may be disposed over the semiconductor substrate 300 in the Z direction. The dummy gate structure 322 may be disposed over the fin structure 310. The dummy gate structure 322 may extend in the Y direction. The dummy gate structure 322 may cover an upper surface and two opposite sidewalls of the fin structure 310. The dummy gate structure 322 may be disposed between the gate structure 321 and the dummy gate structure 323 in the X direction. In an embodiment, the dummy gate structure 322 and the gate structure 321 can have the same structure and material. The doped region 312 is disposed in the fin structure 310. The doped region 312 may be disposed in the fin structure 310 and in the semiconductor substrate 300 under the fin structure 310. The doped region 312 may be disposed on a side of the dummy gate structure 322 and between the dummy gate structure 322 and the gate structure 321. The doped region 312 and the doped region 313 may be disposed on opposite sides of the dummy gate structure 322 in the X direction. The doped region 312 may include a first type dopant or a second type dopant. The doped layer 317 is disposed in the fin structure 310. The doped layer 317 may be disposed over the semiconductor substrate 300 in the Z direction. The doped layer 317 can be completely disposed in the fin structure 310 without extending into the semiconductor substrate 300. The doped layer 317 may be disposed under the dummy gate structure 322 in the Z direction. The doped layer 317 may adjoin the doped region 312 and the doped region 313. The doped layer 317 extends from the doped region 312 to the doped region 313. The doped layer 317 may include a first type dopant or a second type dopant. A lower surface of the doped layer 317 can be higher than a lower surface of the doped region 312 in the Z direction. The doped region 313 can separate the doped layer 317 from the doped layer 318. The doped layer 317 and the doped layer 318 may be disposed on opposite sides of the doped region 313. The doped region 312, the doped region 313 and the second source/drain region 314 can be separated from each other.

In an embodiment, when the transistor 30 includes three or more dummy gate structures disposed between the gate structure 321 and the second source/drain region 314, the configuration of the dummy gate structures, the doped layers and the doped regions in the transistor 30 can be deduced from the above content.

The transistor 30 may include isolation elements 341, a well region 342 and a deep well region 343. The following content takes two isolation elements 341 as an example to illustrate the structure, position and material of the isolation elements, but the present disclosure is not limited thereto; the transistor 30 may include less than two or more than two isolation elements. Two isolation elements 341 may be disposed in the semiconductor substrate 300 and on opposite sides of the fin structure 310. Two isolation elements 341 may be disposed on opposite sides of the gate structure 321. One of the two isolation elements 341 may be disposed on a side of the second source/drain region 314 away from the first source/drain region 311, and the other one of the two isolation elements 341 may be disposed on a side of the first source/drain region 311 away from the second source/drain region 314. An upper surface of the isolation element 341 may be substantially aligned with a lower surface of the fin structure 310. The isolation element 341 may include an insulating material such as silicon oxide. The well region 342 is in the semiconductor substrate 300. The fin structure 310 may be disposed in the well region 342. The well region 342 may surround the fin structure 310. The well region 342 may surround the first source/drain region 311, the second source/drain region 314, the doped region 312, the doped region 313, the doped layer 317 and the doped layer 318. The isolation element 341 can be disposed in the well region 342. The well region 342 may include a first type dopant or a second type dopant. The deep well region 343 is in the semiconductor substrate 300. The well region 342 can be disposed in the deep well region 343. The deep well region 343 may surround the well region 342. The deep well region 343 may include a first type dopant or a second type dopant.

The transistor 30 may includes LDD (low-doped drain) elements 316. The LDD elements 316 are separated from each other. The LDD elements 316 are disposed in the fin structure 310. The LDD elements 316 may be disposed over the semiconductor substrate 300 in the Z direction. The LDD elements 316 can be completely disposed in the fin structure 310 without extending into the semiconductor substrate 300. The LDD elements 316 may be below the gate structure 321 in the Z direction. The LDD elements 316 may include a first type dopant or a second type dopant. Lower surfaces of the LDD elements 316 can be higher than a lower surface of the first source/drain region 311, the lower surface of the doped region 312, the lower surface of the doped region 313 and a lower surface of the second source/drain region 314.

In an embodiment where the transistor 30 includes only one dummy gate structure (e.g., the dummy gate structure 323), one of the LDD elements 316 can be disposed on a side of the first source/drain region 311 facing the doped region 313 and adjoin the first source/drain region 311, and another one of the LDD elements 316 can be disposed on a side of the doped region 313 facing the first source/drain region 311 and adjoin the doped region 313. In an embodiment where the transistor 30 includes two dummy gate structure (e.g., the dummy gate structure 323 and the dummy gate structure 322), one of the LDD elements 316 can be disposed on a side of the first source/drain region 311 facing the doped region 312 and adjoin the first source/drain region 311, and another one of the LDD elements 316 can be disposed on a side of the doped region 312 facing the first source/drain region 311 and adjoin the doped region 312.

The transistor 30 may includes a spacer structure 361. The spacer structure 361 may be disposed on a sidewall of the gate structure 321, a sidewall of the dummy gate structure 322 and a sidewall of the dummy gate structure 323. The spacer structure 361 may include a single-layer structure (not shown) or a multi-layer structure (as shown in FIG. 2). The multi-layer structure of the spacer structure 361 may be formed of different materials. The spacer structure 361 may include an insulating material such as silicon oxide, silicon nitride, silicon oxynitride or silicon carbon-nitride.

The transistor 30 may include contact plugs 331, 332, 333, 334 and 335, and conductive films 351, 353, 354 and 355. The conductive film 351 is disposed between the contact plug 331 and the first source/drain region 311. The contact plug 331 can be electrically connected to the first source/drain region 311 through the conductive film 351. The conductive film 353 is disposed between the contact plug 333 and the doped region 312. The contact plug 333 can be electrically connected to the doped region 312 through the conductive film 353. The conductive film 354 is disposed between the contact plug 334 and the doped region 313. The contact plug 334 can be electrically connected to the doped region 313 through the conductive film 354. The conductive film 355 is disposed between the contact plug 335 and the second source/drain region 314. The contact plug 335 can be electrically connected to the second source/drain region 314 through the conductive film 355. The contact plug 332 is disposed on the gate structure 321 and electrically connected to the gate structure 321. The contact plugs 331, 332, 333, 334 and 335 may include conductive materials such as tungsten (W), copper (Cu), aluminum (AI), titanium aluminum alloy (TiAI), or cobalt tungsten phosphide (CoWP). The conductive films 351, 353, 354 and 355 may include metal silicide such as titanium silicide (TiSi).

The transistor 30 may include an outer doped layer 315 and an outer doped layer 319. The outer doped layer 315 and the outer doped layer 319 are disposed in the fin structure 310. The outer doped layer 315 and the outer doped layer 319 may be disposed over the semiconductor substrate 300 in the Z direction. The outer doped layer 315 and the outer doped layer 319 can be completely disposed in the fin structure 310 without extending into the semiconductor substrate 300. The outer doped layer 315 may adjoin a side of the first source/drain region 311 away from the gate structure 321. The outer doped layer 319 may adjoin a side of the second source/drain region 314 away from the gate structure 321. The outer doped layer 315 and the outer doped layer 319 may include a first type dopant or a second type dopant. A lower surface of the outer doped layer 315 and a lower surface of the outer doped layer 319 may be higher than the lower surface of the first source/drain region 311 and the lower surface of the second source/drain region 314.

In an embodiment, the gate structure 321, the dummy gate structure 322 and the dummy gate structure 323 can be formed simultaneously or can be formed in the same process step. In an embodiment, the LDD elements 316, the doped layer 317, the doped layer 318, the outer doper layer 315 and the outer doped layer 319 can be formed simultaneously or can be formed in the same process step. In an embodiment, the LDD elements 316, the doped layer 317, the doped layer 318, the outer doper layer 315 and the outer doped layer 319 can have the same or substantially the same height in the Z direction, and the height can be the distance from the upper surface of these elements to the lower surface of these elements in the Z direction. In an embodiment, the first source/drain region 311, the second source/drain region 314, the doped region 312 and the doped region 313 can be formed simultaneously or can be formed in the same process step. In an embodiment, the first source/drain region 311, the second source/drain region 314, the doped region 312 and the doped region 313 can have the same or substantially the same height in the Z direction, and the height can be the distance from the upper surface of these elements to the lower surface of these elements in the Z direction.

The LDD elements 316, the doped layer 317, the doped layer 318, the outer doper layer 315 and the outer doped layer 319 may include dopant with the same conductivity type. The first source/drain region 311, the second source/drain region 314, the doped region 312 and the doped region 313 may include dopant with the same conductivity type. The well region 342 and the first source/drain region 311 may include dopants with different conductivity types. In an embodiment, the first type dopant is a N-type dopant, and the second type dopant is a P-type dopant; each of the LDD elements 316, the doped layer 317, the doped layer 318, the outer doper layer 315 and the outer doped layer 319 includes the first type dopant with a first dopant concentration, each of the first source/drain region 311, the second source/drain region 314, the doped region 312 and the doped region 313 includes the first type dopant with a second dopant concentration, and the first dopant concentration is smaller than the second dopant concentration; the well region includes the second type dopant; the deep well region 343 includes the first type dopant. In an embodiment, the dopant may be introduced into the target element by doping techniques or other suitable techniques. The doping technology includes, but is not limited to, thermal diffusion doping technology and ion implantation doping technology.

The dummy gate structure 322 can have a length 322L in the X direction. The dummy gate structure 323 can have a length 323L in the X direction. The length 322L and the length 323L may be less than or equal to 50 nanometers (nm), for example, less than or equal to 40 nm or less than or equal to 36 nm. When the length of the dummy gate structure in the X direction is greater than 50 nm, the doped layer under the dummy gate structure cannot extend continuously under the dummy gate structure, and the doped layer under the dummy gate structure may be divided into two or more parts separated from each other; the discontinuously extended doped layer cannot serve as a carrier channel, thereby failing to improve the protection capability of the ESD/EOS protection device. The length 322L of the dummy gate structure 322 and the length 323L of the dummy gate structure 323 may be the same or different.

A distance between the gate structure 321 and the contact plug 335 in the X direction can be represented as the distance DCG. The distance DCG can be the distance (in the X direction) between the sidewall of the gate structure 321 facing the second source/drain region 314 and the sidewall of the contact plug 335 facing the gate structure 321.

In an embodiment, the transistor includes two dummy gate structures between the gate structure and the second source/drain region (functioned as the drain region), the length of each dummy gate structure in the X direction is 20 nm, the length of the gate structure in the X direction is 135 nm, and the distance DCG is 700 nm. In an embodiment, the transistor includes three dummy gate structures between the gate structure and the second source/drain region (functioned as the drain region), the length of each dummy gate structure in the X direction is 36 nm, the length of the gate structure in the X direction is 135 nm, and the distance DCG is 700 nm.

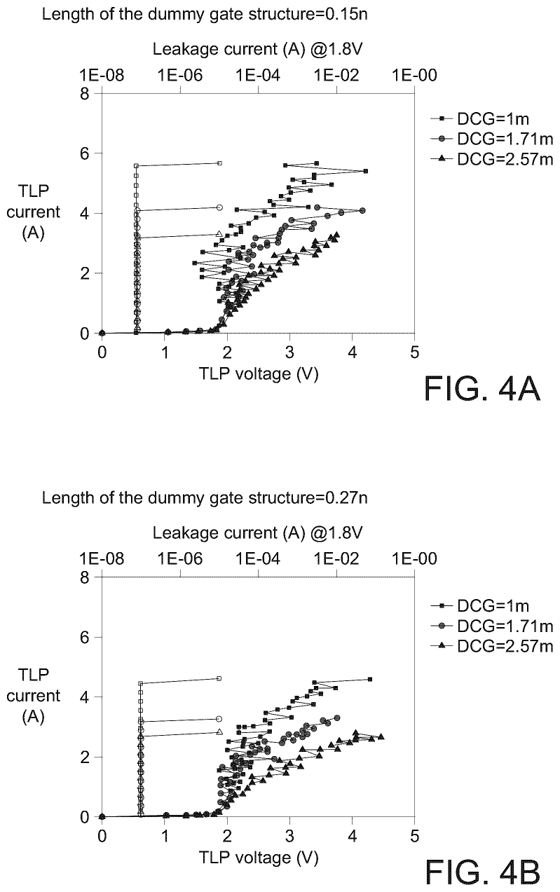

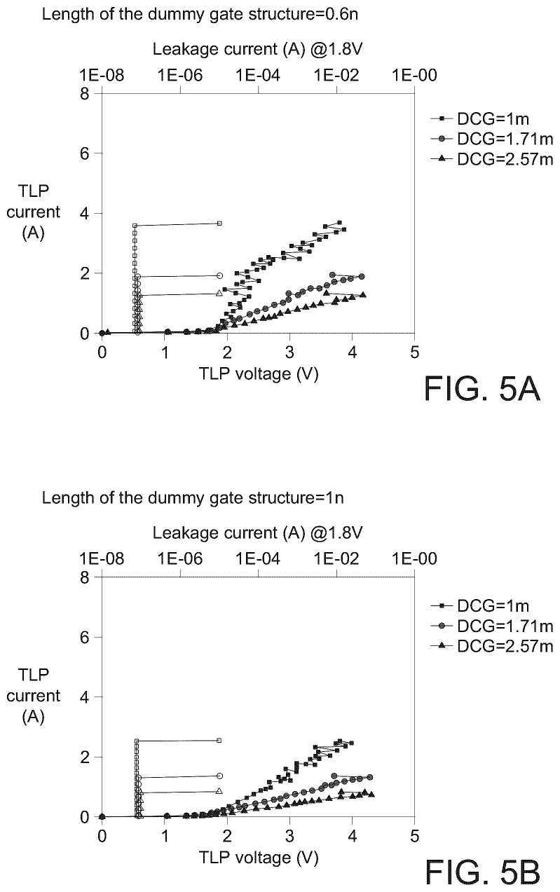

The electrical performance of the ESD/EOS protection devices according to some examples of the present disclosure and the ESD/EOS protection devices of the comparative examples are evaluated by human body model (HBM), transmission line pulse (TLP) test and IEC 61000-4-5 Surge Test published by the International Electrotechnical Commission (IEC), and the relevant parameters are listed in the following TABLE 1. Graphs of current-voltage (I-V) characteristics obtained from TLP tests are shown in FIGS. 4A to 5B. In FIGS. 4A to 5B, the data points represented by solid squares, solid circles and solid triangles and the curves formed by these data points correspond to the Y-axis (TLP current) and the X-axis (TLP voltage) below, and the data points represented by hollow squares, hollow circles and hollow triangles and the curves formed by these data points correspond to the Y-axis (TLP current) and the X-axis (leakage current) above. The HBM can simulate the discharge which occurs when a charged human touches or approaches a device, and the test results are listed in the HBM column in the following TABLE 1. The TLP test can generate an adjustable and fast-rising pulse currents, and the device is applied with a pulse current with a condition to obtain an I-V point at each time; the device is continuously applied with pulse currents with different conditions until the leakage current exceeds the specification value. The IEC 61000-4-5 surge test can simulate the surge voltages and currents which occur when the device is struck by lightning or during switching, so as to evaluate the anti-interference capability of the device; the test results are listed in the EOS column in the following TABLE 1. Examples 1 to 6 have the structures shown in FIG. 2, but the number of dummy gate structures, and/or the length of each dummy gate structure in the X direction, and/or the distance DCG in the X direction of these examples may be different. Examples 1 to 3 correspond to FIG. 4A. Examples 4 to 6 correspond to FIG. 4B. Comparative Examples 1 to 6 have the structures shown in FIG. 2, but Comparative Examples 1 to 6 do not include the doped layers under the dummy gate structures. In Comparative Examples 1 to 6, the number of dummy gate structures, and/or the length of each dummy gate structure in the X direction, and/or the distance DCG in the X direction may be different. Comparative Examples 1 to 3 correspond to FIG. 5A. Comparative Examples 4 to 6 correspond to FIG. 5B. In Examples 1 to 6 and Comparative Examples 1 to 6, m and n are integers or non-integers greater than zero, all m are the same value, and all n are the same value. Therefore, the distance DOG of Example 2 can be understood as 1.71 times the distance DOG of Example 1, and the length of the dummy gate structure of Examples 1 to 3 can be understood as 0.15 times the length of the dummy gate structure of Comparative Examples 4 to 6.

TABLE 1

| | | | | | |
|---|---|---|---|---|---|
| | Distance | Number of | TLP secondary | | |
| | DCG | dummy gate | breakdown | HBM | EOS |
| Example | (μm) | structures | current Iₜ₂ (A) | (kV) | (V) |

The length of each dummy gate structure in
the X direction = 0.15n (with doped layer(s))

| | | | | | | |
|---|---|---|---|---|---|---|
| 1 | 1 | m | 2 | 5.6 | 3.8 | 17 |
| 2 | 1.71 | m | 5 | 4.1 | 4.2 | 20 |
| 3 | 2.57 | m | 8 | 3.2 | 5.0 | 22 |

The length of each dummy gate structure in
the X direction = 0.27n (with doped layer(s))

| | | | | | | |
|---|---|---|---|---|---|---|
| 4 | 1 | m | 3 | 4.5 | 4.2 | 16 |
| 5 | 1.71 | m | 6 | 3.2 | 4.8 | 19 |
| 6 | 2.57 | m | 7 | 2.7 | 4.0 | 22 |

| | | | | | |
|---|---|---|---|---|---|
| | Distance | Number of | TLP secondary | | |
| Comparative | DCG | dummy gate | breakdown | HBM | EOS |
| Example | (μm) | structures | current Iₜ₂ (A) | (kV) | (V) |

The length of each dummy gate structure in
the X direction = 0.6n (without doped layer(s))

| | | | | | | |
|---|---|---|---|---|---|---|
| 1 | 1 | m | 1 | 3.6 | 3.4 | 16 |
| 2 | 1.71 | m | 3 | 1.9 | 3.0 | 19 |
| 3 | 2.57 | m | 5 | 1.3 | 1.8 | 19 |

The length of each dummy gate structure in
the X direction = 1n (without doped layer(s))

| | | | | | | |
|---|---|---|---|---|---|---|
| 4 | 1 | m | 1 | 2.5 | 2.2 | 17 |
| 5 | 1.71 | m | 2 | 1.3 | 2.0 | 20 |
| 6 | 2.57 | m | 4 | 0.8 | 1.0 | 22 |

As shown in FIGS. 4A to 5B and TABLE 1, Examples 1 to 6 have lower on-resistance (Ron) and higher secondary breakdown current (Iₜ₂) as compared with Comparative Examples 1 to 6, which means that providing the dummy gate structure and the doped layer under the dummy gate structure in the transistor can enhance the protection capability against ESD events and EOS events. In addition, TABLE 1 shows that increasing the distance DCG can enhance the protection capability against EOS events.

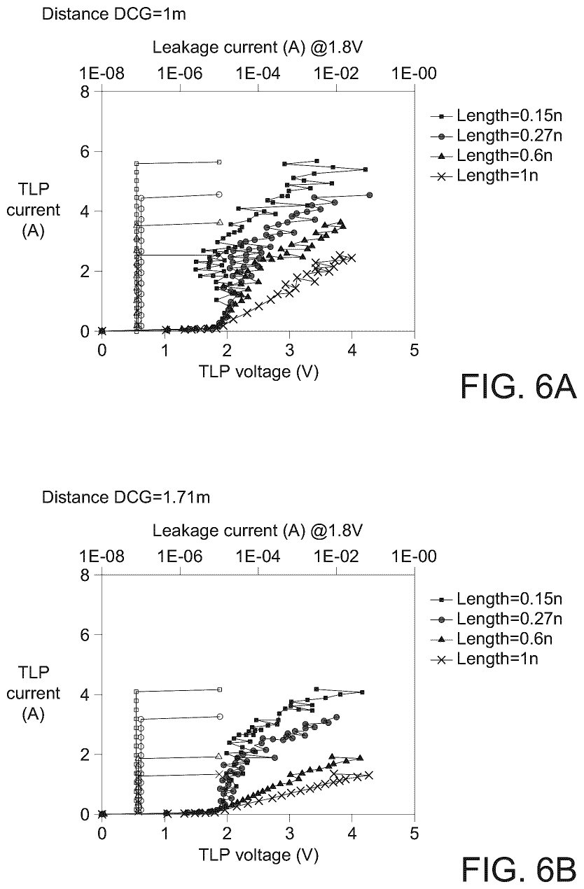

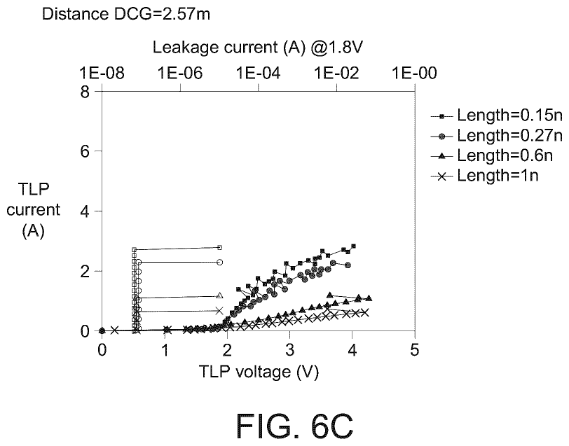

Referring to FIGS. 6A to 6C, FIG. 6A shows graphs of current-voltage (I-V) characteristics obtained from TLP tests in Example 1, Example 4, Comparative Example 1 and Comparative Example 4, FIG. 6B shows graphs of current-voltage (I-V) characteristics obtained from TLP tests in Example 2, Example 5, Comparative Example 2 and Comparative Example 5, and FIG. 6C shows graphs of current-voltage (I-V) characteristics obtained from TLP tests in Example 3, Example 6, Comparative Example 3 and Comparative Example 6. In FIGS. 6A to 6C, the data points represented by solid squares, solid circles, solid triangles and thick crosses (x) and the curves formed by these data points correspond to the Y-axis (TLP current) and the X-axis (TLP voltage) below, and the data points represented by hollow squares, hollow circles, hollow triangles and thin crosses (x) and the curves formed by these data points correspond to the Y-axis (TLP current) and the X-axis (leakage current) above. As shown in FIGS. 6A to 6C and TABLE 1, when the distance DCG is the same, increasing the number of dummy gate structures can increase the voltage that can be withstood under the HBM, which means that increasing the number of dummy gate structures can enhance the protection capability against ESD events.

The present disclosure provides an ESD/EOS protection device including at least one dummy gate structure between the gate structure and the source/drain region, and at least one doped layer under the at least one dummy gate structure, the continuously extended doped layer under the dummy gate structure can serve as a carrier channel to increase the driving current of the transistor and reduce the on-resistance of the transistor, which enhance the protection capability of the ESD/EOS protection device against ESD events and EOS events. Moreover, the configuration of the present disclosure can be integrated into the existing manufacturing process of fin field effect transistor without using an additional mask, thereby simplifying the manufacturing process and reducing costs.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An ESD/EOS protection device, comprising:
a fin structure formed of a semiconductor material and over a semiconductor substrate;
a first source/drain region in the fin structure;
a second source/drain region in the fin structure;
a gate structure over the fin structure and between the first source/drain region and the second source/drain region;
a first dummy gate structure over the fin structure;
a first doped region in the fin structure and between the first source/drain region and the second source/drain region; and
a first doped layer under the first dummy gate structure and extending from the second source/drain region to the first doped region, wherein a lower surface of the first doped layer is higher than a lower surface of the first doped region.

2. The ESD/EOS protection device according to claim 1, wherein the first doped layer is over the semiconductor substrate.

3. The ESD/EOS protection device according to claim 1, wherein the first doped layer comprises a first type dopant with a first dopant concentration, the second source/drain region comprises the first type dopant with a second dopant concentration, and the first dopant concentration is smaller than the second dopant concentration.

4. The ESD/EOS protection device according to claim 1, further comprising an isolation element in the semiconductor substrate and on a side of the second source/drain region away from the first source/drain region.

5. The ESD/EOS protection device according to claim 4, further comprising a well region in the semiconductor substrate, wherein the isolation element is in the well region.

6. The ESD/EOS protection device according to claim 5, wherein each of the second source/drain region, the first source/drain region and the first doped region comprises a first type dopant, and the well region comprises a second type dopant different from the first type dopant.

7. The ESD/EOS protection device according to claim 5, wherein the well region surrounds the first source/drain region, the second source/drain region, the first doped region and the first doped layer.

8. The ESD/EOS protection device according to claim 1, wherein the fin structure extends along a first direction, the first dummy gate structure extends along a second direction perpendicular to the first direction, and a length of the first dummy gate structure along the first direction is smaller than 50 nm.

9. The ESD/EOS protection device according to claim 8, wherein the length of the dummy gate structure along the first direction is smaller than 40 nm.

10. The ESD/EOS protection device according to claim 1, further comprising:
a second dummy gate structure over the fin structure;
a second doped region in the fin structure; and
a second doped layer under the second dummy gate structure and extending from the first doped region to the second doped region,
wherein the first doped layer and the second doped layer are separated from each other.

11. The ESD/EOS protection device according to claim 10, wherein the first doped layer and the second doped layer are on opposite sides of the first doped region.

12. The ESD/EOS protection device according to claim 10, further comprising a well region in the semiconductor substrate and surrounding the first doped layer, the first doped region, the second doped layer and the second doped region.

13. The ESD/EOS protection device according to claim 10, wherein the fin structure extends along a first direction, the first dummy gate structure extends along a second direction perpendicular to the first direction, and a length of the first dummy gate structure along the first direction and a length of the second dummy gate structure along the first direction are smaller than 50 nm.

14. The ESD/EOS protection device according to claim 10, further comprising LDD elements on a side of the first source/drain region and a side of the second doped region, wherein the LDD elements are separated from each other.

15. An ESD/EOS protection device, comprising:
a fin structure formed of a semiconductor material and over a semiconductor substrate;
a first source/drain region in the fin structure;
a second source/drain region in the fin structure;
a gate structure over the fin structure and between the first source/drain region and the second source/drain region;
a first dummy gate structure over the fin structure;
a first doped region in the fin structure and between the first source/drain region and the second source/drain region;
a first doped layer under the first dummy gate structure and extending from the second source/drain region to the first doped region;
a second dummy gate structure over the fin structure;
a second doped region in the fin structure; and
a second doped layer under the second dummy gate structure and extending from the first doped region to the second doped region,
wherein the first doped layer and the second doped layer are separated from each other.

16. The ESD/EOS protection device according to claim 15, further comprising LDD elements on a side of the first source/drain region and a side of the second doped region, wherein the LDD elements are separated from each other, and the side of the first source/drain region faces the side of the second doped region.

17. The ESD/EOS protection device according to claim 16, wherein the first doped layer comprises a first type dopant with a first dopant concentration, the second doped layer comprises the first type dopant with the first dopant concentration, and each of the LDD elements comprises the first type dopant with the first dopant concentration.

18. The ESD/EOS protection device according to claim 17, wherein the second source/drain region comprises the first type dopant with a second dopant concentration, and the first dopant concentration is smaller than the second dopant concentration.

19. The ESD/EOS protection device according to claim 15, wherein the fin structure extends along a first direction, the first dummy gate structure extends along a second direction perpendicular to the first direction, and a length of the first dummy gate structure along the first direction is smaller than 50 nm.

20. The ESD/EOS protection device according to claim 19, wherein the length of the dummy gate structure along the first direction and a length of the second dummy gate structure along the first direction are smaller than 40 nm.
